(19) United States
(12) Patent Application Publication
(10) Pub. No.: US 2026/0371865 A1
(43) Pub. Date: Nov. 19, 2026

(54) DISPLAY PANEL, DISPLAY DEVICE, AND FORMING METHOD OF PIN DIODE

(71) Applicant: Wuhan Tianma Micro-Electronics Co., Ltd., Wuhan (CN)

(72) Inventor: Dan HUANG, Wuhan (CN)

(21) Appl. No.: 19/254,973

(22) Filed: Jun. 30, 2025

(30) Foreign Application Priority Data
May 13, 2025 (CN) 202510616537.9

(51) Int. Cl. H10K 59/13; H10F 30/223; H10K 59/12

(52) U.S. Cl. CPC H10K 59/13; H10F 30/223; H10K 59/1201

(57) ABSTRACT

Display panel, display device, and forming method of PIN diode are provided. The display panel includes a substrate; an array layer on a side of the substrate; a PIN diode integrated within the array layer, the PIN diode including an N-type semiconductor layer, an intrinsic semiconductor layer and a P-type semiconductor layer; and the P-type semiconductor layer including doping ions implanted based on ion implantation, the doping ions including first doping ions, and an ion implantation depth of the first doping ions being smaller than a thickness of the P-type semiconductor layer.

### CROSS-REFERENCE TO RELATED APPLICATION

This application claims priority of Chinese Patent Application No.:2025106165379, filed on May 13, 2025, the entire contents of which are hereby incorporated by reference.

### FIELD OF THE DISCLOSURE

The present disclosure generally relates to the field of display technology and, more particularly, relates to a display panel, a display device, and a forming method of PIN diode.

### BACKGROUND

With development of display technology, display panels have become increasingly widespread, and have gradually been applied to mobile phones, TVs, tablets, car monitors, etc.

At present, PIN diodes are commonly arranged in display panels to enable additional functions, such as full-screen fingerprint recognition and automatic screen brightness adjustment based on ambient light.

However, in current display panels integrated with PIN diodes, an N-type semiconductor layer, an intrinsic semiconductor layer, and a P-type semiconductor layer are all formed using a chemical vapor deposition (CVD) process. The P-type and N-type semiconductor layers are formed using the CVD process in two different chambers, resulting in a cumbersome formation process and high production costs.

### BRIEF SUMMARY OF THE DISCLOSURE

One aspect of the present disclosure provides a display panel. The display panel includes a substrate; an array layer on a side of the substrate; a PIN diode integrated within the array layer, the PIN diode including an N-type semiconductor layer, an intrinsic semiconductor layer and a P-type semiconductor layer; and the P-type semiconductor layer including doping ions implanted based on ion implantation, the doping ions including first doping ions, and an ion implantation depth of the first doping ions being smaller than a thickness of the P-type semiconductor layer.

Another aspect of the present disclosure provides a method of forming a PIN diode. The method includes forming a stacked structure of an N-type semiconductor layer and an intrinsic semiconductor layer; forming a film layer to be processed on a side of the intrinsic semiconductor layer facing away from the N-type semiconductor layer; and implanting doping ions into the film layer to be processed by ion implantation to form a P-type semiconductor layer, the doping ions including first doping ions, and the ion implantation depth of the first doping ions being smaller than the thickness of the P-type semiconductor layer.

Another aspect of the present disclosure provides a display device including a display panel. The display panel includes a substrate; an array layer on a side of the substrate; a PIN diode integrated within the array layer, the PIN diode including an N-type semiconductor layer, an intrinsic semiconductor layer and a P-type semiconductor layer; and the P-type semiconductor layer including doping ions implanted based on ion implantation, the doping ions including first doping ions, and an ion implantation depth of the first doping ions being smaller than a thickness of the P-type semiconductor layer.

Other aspects of the present disclosure can be understood by a person skilled in the art in light of the description, the claims, and accompanying drawings of the present disclosure.

### BRIEF DESCRIPTION OF THE DRAWINGS

The above and other features, advantages, and aspects of various embodiments of the present disclosure will become more apparent with reference to accompanying drawings and following specific implementation methods. Throughout the accompanying drawings, same or similar reference numbers refer to same or similar elements. It is understood that the accompanying drawings are schematic and that components and elements are not necessarily drawn to scale.

FIG. 1 illustrates a schematic diagram of a display panel consistent with various embodiments of the present disclosure;

FIG. 2 illustrates a schematic diagram of another display panel consistent with various embodiments of the present disclosure;

FIG. 3 illustrates a schematic diagram of another display panel consistent with various embodiments of the present disclosure;

FIG. 4 illustrates a schematic diagram of another display panel consistent with various embodiments of the present disclosure;

FIG. 5 illustrates a flow chart of a method for forming a PIN diode consistent with various embodiments of the present disclosure;

FIG. 6 illustrates a flow chart of a method for forming another PIN diode consistent with various embodiments of the present disclosure;

FIG. 7 illustrates a flow chart of a method for forming another PIN diode consistent with various embodiments of the present disclosure;

FIG. 8 illustrates a flow chart of a method for forming another PIN diode consistent with various embodiments of the present disclosure;

FIG. 9 illustrates a schematic diagram of a corresponding photocurrent under different ion implantation energies with a same first ion implantation dose consistent with various embodiments of the present disclosure;

FIG. 10 illustrates a schematic diagram of a projection range under a first ion implantation energy and a first ion implantation dose consistent with various embodiments of the present disclosure;

FIG. 11 illustrates a schematic diagram of a projection range under a second ion implantation energy and a first ion implantation dose consistent with various embodiments of the present disclosure;

FIG. 12 illustrates a flow chart of a method for forming another PIN diode consistent with various embodiments of the present disclosure;

FIG. 13 illustrates a schematic diagram of a corresponding photocurrent under a first ion implantation energy and different doping ions consistent with various embodiments of the present disclosure;

FIG. 14 illustrates a schematic diagram of a corresponding photocurrent under second ion implantation energy and different doping ions consistent with various embodiments of the present disclosure;

FIG. 15 illustrates a schematic diagram of a projection range under a first ion implantation energy, B doping, and a first ion implantation dose of B doping ions consistent with various embodiments of the present disclosure;

FIG. 16 illustrates a schematic diagram of a projection range under a first ion implantation energy and BF doping, with a total dose of BF doping being a first ion implantation dose, consistent with various embodiments of the present disclosure;

FIG. 17 illustrates a flow chart of a method for forming another PIN diode consistent with various embodiments of the present disclosure;

FIG. 18 illustrates a schematic diagram of a corresponding photocurrent under a same ion implantation energy and different ion implantation doses consistent with various embodiments of the present disclosure;

FIG. 19 illustrates a flow chart for forming intrinsic semiconductor layers consistent with various embodiments of the present disclosure;

FIG. 20 illustrates a flow chart of a method for forming another PIN diode consistent with various embodiments of the present disclosure; and

FIG. 21 illustrates a schematic diagram of a display device consistent with various embodiments of the present disclosure.

### DETAILED DESCRIPTION

Embodiments of the present disclosure will be described below with reference to the accompanying drawings in the embodiments of the present disclosure. Terms used herein are intended solely to explain specific embodiments of the present disclosure and are not meant to limit the present disclosure. A person skilled in the art will recognize that, with technological development and emergences of new scenarios, technical solutions provided by the embodiments of the present disclosure are also applicable to similar technical problems.

It should be noted that the directional terms appearing in the present disclosure are based on relative positional relationships shown in the accompanying drawings and cannot be construed as absolute limitations on the present disclosure.

To make the above objects, features and advantages of the present disclosure more apparent and understandable, the present disclosure will be further described in detail below with reference to the accompanying drawings and specific embodiments.

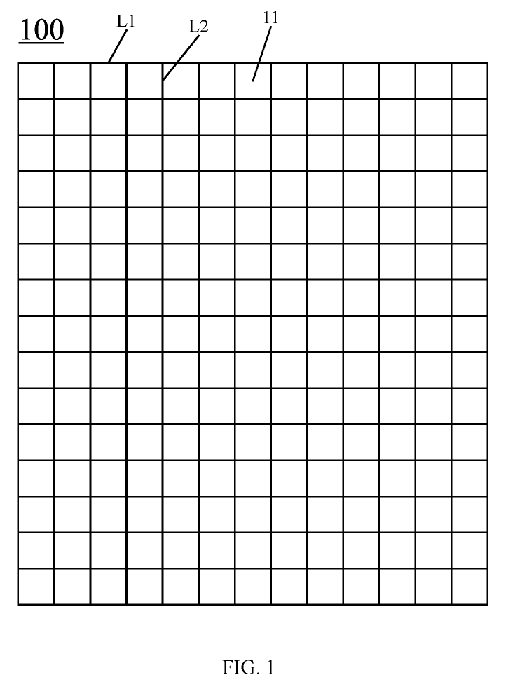

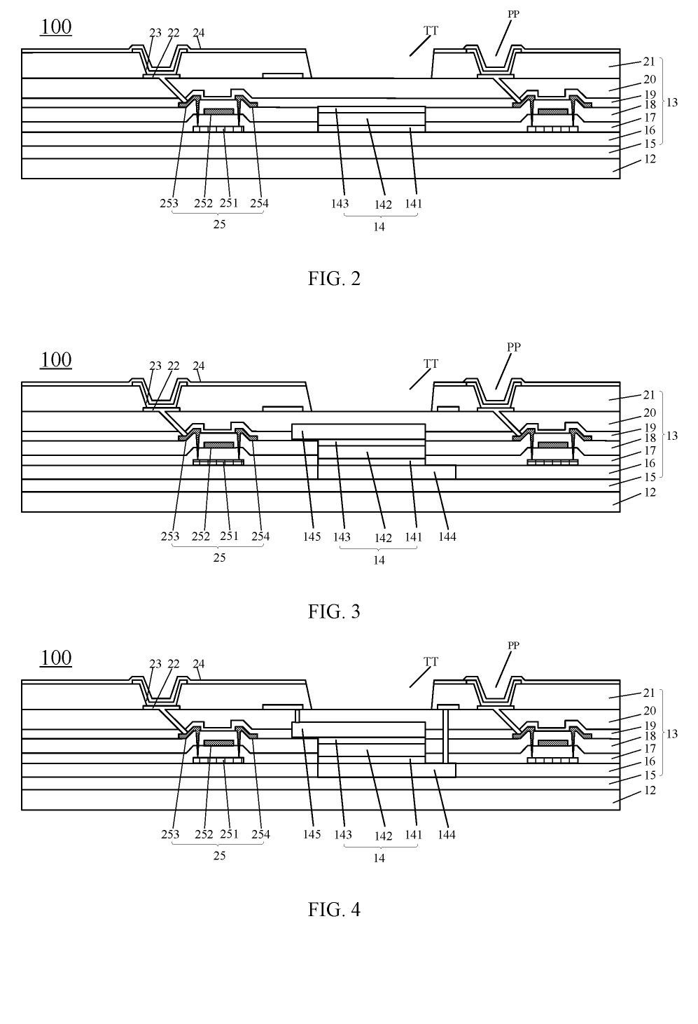

FIG. 1 illustrates a schematic diagram of a display panel consistent with various embodiments of the present disclosure. FIG. 2 illustrates a schematic diagram of another display panel consistent with various embodiments of the present disclosure. A display panel 100 includes a substrate 12; an array layer 13 on a side of the substrate 12; and a PIN diode 14 integrated into the array layer 13. The PIN diode 14 includes an N-type semiconductor layer 141, an intrinsic semiconductor layer 142 and a P-type semiconductor layer 143.

The P-type semiconductor layer 143 includes doping ions implanted based on ion implantation. The doping ions include first doping ions, whose implantation depth is less than a thickness of the P-type semiconductor layer 143.

Specifically, as shown in FIG. 1 in one embodiment, the display panel includes a first signal line L1 extending along a row direction, and a second signal line L2 extending along a column direction. The first signal line L1 intersects the second signal line L2, and an intersection thereof defines a plurality of sub-pixels 11 arranged in an array. The first signal line L1 extending along the row direction may include a Scan signal line, a Vref signal line, a DVH signal line, and the like. The second signal line L2 extending along the column direction may include a Data signal line, a PVDD signal line, and the like.

The substrate 12 is a flexible insulating material with stretchable and bendable properties. The flexible insulating material includes, but are not limited to, polyimide (PI), polycarbonate (PC) and polyethylene terephthalate (PET).

As shown in FIG. 2, the array layer 13 includes but is not limited to a first insulation layer 15, a second insulation layer 16, a third insulation layer 17, a fourth insulation layer 18, a passivation layer 19, a planarization layer 20 and a pixel definition layer 21. The pixel definition layer 21 has a plurality of sub-pixel opening areas PP and a plurality of light-transmitting areas TT. A pixel opening area PP is arranged with an anode layer 22, a light-emitting layer 23 and a cathode layer 24 to form light-emitting elements required by the sub-pixels 11.

As shown in FIG. 2, the display panel 100 further includes a transistor 25, which forms a pixel circuit and other functional circuits. The transistor 25 includes an active layer 251, a gate electrode 252, a source electrode 253 and a drain electrode 254. The active layer 251 is on a side of the second insulating layer 16 facing away from the substrate 12. The gate electrode 252 is on a side of the third insulating layer 17 facing away from the substrate 12. The source electrode 253 and the drain electrode 254 are on a same layer and on a side of the fourth insulating layer 18 away from the substrate 12. The passivation layer 19 is arranged on a side of the source electrode 253 and the drain electrode 254 facing away from the substrate 12. The planarization layer 20 is arranged on a side of the passivation layer 19 facing away from the substrate 12. The pixel definition layer 21 is arranged on a side of the planarization layer 20 facing away from the substrate 12.

A light-transmitting area TT is arranged between at least part of two adjacent sub-pixels 11, and the orthographic projection of the light-transmitting area TT at least completely covers the intrinsic semiconductor layer 142 to ensure that light can illuminate the intrinsic semiconductor layer 142.

In one embodiment, the PIN diode 14 includes, but is not limited to, a photoelectric PIN diode, which is used as an example for description. A conventional diode directly forms a PN junction using an N-type doped semiconductor layer and a P-type doped semiconductor layer. However, in the embodiment, the PIN diode 14 adds a lightly doped intrinsic semiconductor layer 142 arranged between the P-type semiconductor layer 143 and the N-type semiconductor layer 141.

FIG. 3 illustrates a schematic diagram of another display panel consistent with various embodiments of the present disclosure. In one embodiment, the PIN diode 14 further includes a first electrode 144 connected to the N-type semiconductor layer 141 and a second electrode 145 connected to the P-type semiconductor layer 143.

FIG. 4 illustrates a schematic diagram of another display panel consistent with various embodiments of the present disclosure. In one embodiment, the anode layer 22 is connected to the P-type semiconductor layer 143 and/or the N-type semiconductor layer 141. As shown in FIG. 4, the N-type semiconductor layer 141 is electrically connected to the anode layer 22 through the first electrode 144, and the P-type semiconductor layer 143 is electrically connected to the anode layer 22 through the second electrode 145.

Since the anode layer 22 includes a few independent anode units, some anode units that are not used to form the sub-pixel 11 can be formed during a formation of the anode layer 22 to establish an electrical connection with the PIN diode 14, thereby simplifying a circuit connection.

A photoelectric PIN diode operates under reverse bias and generates photocurrent in a presence of light. A size of a photocurrent of the PIN diode is proportional to an intensity of light. Specifically, when a reverse bias is applied to a PN junction, a direction of an external electric field aligns with a direction of a built-in electric field of the PN junction, a potential barrier is strengthened, and carriers are basically depleted near an PN junction interface to form a depletion region. When a light beam is incident on the PN junction and a photon energy exceeds a band gap of a semiconductor material, electrons in a valence band absorb the photon energy and transition to a conduction band to generate electron-hole pairs. In the depletion region, under an influence of the built-in electric field, electrons drift toward an N region and holes drift toward a P region. If an external circuit connected to the PN junction forms a closed loop, a photocurrent will be formed. As the incident light power varies, the photocurrent changes proportionally, thereby converting an optical signal into an electrical signal.

Based on the above, in one embodiment, since the array layer 13 of the display panel 100 uses ion implantation to form certain film layers during a forming process, that is, a mature ion implantation process already exists on the production line of the array layer 13. Therefore, the PIN diode 14 is first integrated and disposed within the array layer 13 in the present disclosure. During a formation of the array layer 13, the P-type semiconductor layer 143 is formed using an ion implantation method already employed in the formation of the array layer 13. Compared with the existing technologies, the above method simplifies the forming process and reduces production costs.

The photocurrent of the PIN diode 14 depends on a concentration and a movement speed of minority carriers in the PIN diode 14. An ion implantation method causes the first doping ions to diffuse to the intrinsic semiconductor layer 142, resulting in an expansion of a space charge area of the PN junction, a relative narrowing of the depletion layer, a reduction in the number of generated minority carriers, and a decrease in photocurrent. In the embodiment, considering that the first doped ions implanted in the P-type semiconductor layer based on ion implantation may diffuse into the intrinsic semiconductor layer 142 and affect a photoelectric performance of the PIN diode 14. Therefore, in the present disclosure, an ion implantation depth of the first doping ions is arranged to be less than the thickness of the P-type semiconductor layer 143. An area of the P-type semiconductor layer 143 not directly implanted with the first doping ions provides a diffusion space for migrating the first doping ions, thereby minimizing a diffusion depth of the first doped ions into the intrinsic semiconductor layer 142 as much as possible, resulting in a narrow PN junction space charge area, a relatively wider depletion layer, an increased number of generated minority carriers, and an higher photocurrent to ensure the photoelectric performance of the PIN diode 14.

In one optional embodiment, the P-type semiconductor layer 143 is formed by ion implantation using an ion implantation (IMP) process.

In one optional embodiment, the doping ions further include second doping ions, which have a greater ion mass of the first doping ions.

Specifically, in the embodiment, the first doping ions are B ions, that is, the P-type semiconductor layer 143 is formed by an implantation of B ions. The second doping ions include, but are not limited to, at least one of F ions and Ar ions. Under a same ion implantation energy, ions with greater mass move more slowly, while ions with smaller mass move more quickly. To prevent the first doping ions from diffusing rapidly and increasing the ion implantation depth, the second doping ions are co-implanted with the first doping ions. The second doping ions are used to slow down or buffer the diffusion of the first doping ions to deeper areas, thereby minimizing the diffusion depth of the first doping ions into the intrinsic semiconductor layer 142 and ensuring the optoelectronic performance of the PIN diode 14.

By introducing second doping ions, such as Ar ions and/or F ions, a proportion of B ions is reduced. Therefore, under a same ion implantation energy, both an implantation depth and a dose of B ions decrease, thereby achieving a purpose of reducing B ion diffusion depth.

In one optional embodiment, a film formation speed of the P-type semiconductor layer 143 is less than 25 % than a film formation speed of the intrinsic semiconductor layer 142.

Specifically, in the embodiment, the film formation speed of the P-type semiconductor layer 143 is less than 25 % than the film formation speed of the intrinsic semiconductor layer 142, indicating that the formed P-type semiconductor layer 143 is denser than the intrinsic semiconductor layer 142, thereby slowing down the diffusion speed of the first doping ions in the P-type semiconductor layer 143. An interface between the P-type semiconductor layer 143 and intrinsic semiconductor layer 142 further reduces the diffusion speed of the first doped ions, thereby minimizing the diffusion depth of the first doped ions into the intrinsic semiconductor layer 142, ensuring the photoelectric performance of the PIN diode 14.

When the film formation speed of the P-type semiconductor layer 143 is more than 25 % slower than the film formation speed of the intrinsic semiconductor layer 142, e.g., the film formation speed of the P-type semiconductor layer 143 is less than 40 % than the film formation speed of the intrinsic semiconductor layer 142, the density of the P-type semiconductor layer 143 increases. Although the diffusion speed of the first doping ions in the P-type semiconductor layer 143 can be further reduced, there may be cases where the first doping ions cannot fully diffuse throughout effective areas of P-type semiconductor layer 143, resulting in an area that is not doped with the first doping ions between an area of the P-type semiconductor layer 143 doped with first doping ions and the intrinsic semiconductor layer 142, which in turn affects the photoelectric performance of the PIN diode 14.

When the film formation speed of the P-type semiconductor layer 143 is less than the film formation speed of the intrinsic semiconductor layer 142 by less than 25 %, e.g., when the film formation speed of the P-type semiconductor layer 143 is less than the film formation speed of the intrinsic semiconductor layer 142 by less than 15 %, a film density difference between the P-type semiconductor layer 143 and the intrinsic semiconductor layer 142 is small, which fails to slow down the diffusion speed of the first doped ions and to effectively reduce the diffusion depth of the first doped ions into the intrinsic semiconductor layer 142, thereby affecting the photoelectric performance of the PIN diode 14.

Therefore, in the embodiment, the film formation speed of the P-type semiconductor layer 143 is arranged to be less than 25 % than the film formation speed of the intrinsic semiconductor layer 142, to minimize the depth of diffusion of the first doping ions into the intrinsic semiconductor layer 142 as much as possible and ensure the photoelectric performance of the PIN diode 14.

In one optional embodiment, the ion implantation depth of the first doped ions is H, the thickness of the P-type semiconductor layer 143 is G, and H=G/2.

Specifically, in the embodiment, when forming the P-type semiconductor layer 143, the first doping ions are implanted to a depth equal to half thickness of the P-type semiconductor layer 143, while the remaining half-thickness of the P-type semiconductor layer 143 provides a diffusion space for the first doping ions. Under the condition of H=G/2 and the first doping ions can fully diffuse throughout the P-type semiconductor layer 143, none or very few diffuse into the intrinsic semiconductor layer 142 diffuse into the intrinsic semiconductor layer 142, thereby minimizing the diffusion depth of the first doped ions into the intrinsic semiconductor layer 142 as much as possible and ensuring the photoelectric performance of the PIN diode 14.

When H<G/2, although the first doped ions can be guaranteed not to diffuse into the intrinsic semiconductor layer 142, there may be cases where the first doping ions cannot fully diffuse throughout effective areas of P-type semiconductor layer 143, resulting in an area that is not doped with the first doping ions between an area of the P-type semiconductor layer 143 doped with first doping ions and the intrinsic semiconductor layer 142, which in turn affects the photoelectric performance of the PIN diode 14.

When H>G/2, although the first doped ions can be guaranteed to diffuse into the entire P-type semiconductor layer 143, more first doped ions may diffuse into the intrinsic semiconductor layer 142, and the diffusion depth of the first doped ions into the intrinsic semiconductor layer 142 cannot be reduced, which affects the photoelectric performance of the PIN diode 14.

Therefore, in the embodiment, H=G/2 is set. While ensuring that the first doped ions diffuse to the entire P-type semiconductor layer 143, none or very few first doped ions diffuse into the intrinsic semiconductor layer 142, thereby minimizing the diffusion depth of the first doped ions into the intrinsic semiconductor layer 142 and ensuring the photoelectric performance of the PIN diode 14.

In one optional embodiment, a thickness of the P-type semiconductor layer 143 ranges from 300 angstroms to 500 angstroms, e.g., the thickness may be 300 angstroms, 350 angstroms, 400 angstroms or 500 angstroms or the like. A thickness of the intrinsic semiconductor layer 142 ranges from 5000 angstroms to 8000 angstroms, e.g., the thickness may be 5000 angstroms, 6650 angstroms, or 8000 angstroms, or the like. A thickness of the N-type semiconductor layer 141 ranges from 1500 angstroms to 2500 angstroms, e.g., the thickness may be 1500 angstroms, 1750 angstroms, or 2000 angstroms, or the like.

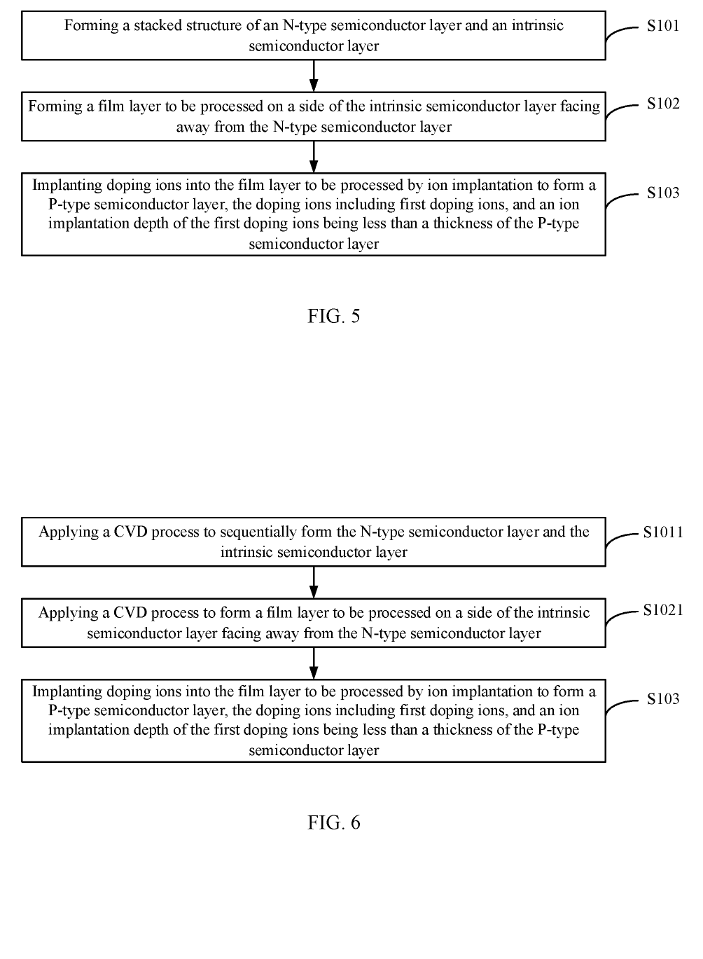

Based on the above embodiments, in one embodiment, a method for forming a PIN diode is provided. FIG. 5 illustrates a flow chart of a method for forming a PIN diode consistent with various embodiments of the present disclosure. The method for forming a PIN diode provided in the embodiment is used to form the PIN diode 14 described in any of the above embodiments. The method for forming a PIN diode includes following steps.

S101: forming a stacked structure of an N-type semiconductor layer 141 and an intrinsic semiconductor layer 142.

S102: forming a film layer to be processed on a side of the intrinsic semiconductor layer 142 facing away from the N-type semiconductor layer 141.

S103: implanting doping ions into the film layer to be processed by ion implantation to form a P-type semiconductor layer 143, the doping ions including first doping ions, and an ion implantation depth of the first doping ions being less than a thickness of the P-type semiconductor layer 143.

Specifically, in one embodiment, the P-type semiconductor layer 143 is formed by implanting the first doping ions into a film layer to be processed using ion implantation. A photocurrent of the PIN diode 14 depends on a concentration and a movement speed of minority carriers in the PIN diode 14. Ion implantation may cause the first doping ions to diffuse into the intrinsic semiconductor layer 142, resulting in a larger space charge region at the PN junction, a relatively narrower depletion layer, fewer generated minority carriers, and a reduction in photocurrent of the PIN diode 14. That is, in the embodiment, it is considered that the first doping ions implanted into the P-type semiconductor layer 143 via ion implantation may diffuse to the intrinsic semiconductor layer 142 and affect a photoelectric performance of the PIN diode 14. Therefore, in the present disclosure, an ion implantation depth of the first doped ions is less than a thickness of the P-type semiconductor layer 143. An area of the P-type semiconductor layer 143 where the first doped ions are not directly implanted provides a diffusion space for the first doped ions, thereby minimizing a diffusion depth of the first doped ions into the intrinsic semiconductor layer 142. Therefore, the PN junction space charge area becomes smaller, the depletion layer becomes relatively wider, number of generated minority carriers increases, and the photocurrent increases to ensure the photoelectric performance of the PIN diode 14.

FIG. 6 illustrates a flow chart of a method for forming another PIN diode consistent with various embodiments of the present disclosure. In one optional embodiment, an implementation method of S101, ‘forming a stacked structure of an N-type semiconductor layer 141 and an intrinsic semiconductor layer 142,’ is as follows:

S1011: applying a CVD process to sequentially form the N-type semiconductor layer 141 and the intrinsic semiconductor layer 142.

An implementation method of S102, ‘forming a film layer to be processed a side of the intrinsic semiconductor layer 142 facing away from the N-type semiconductor layer 141,’ is as follows:

S1021: applying a CVD process to form a film layer to be processed on a side of the intrinsic semiconductor layer 142 facing away from the N-type semiconductor layer 141.

Specifically, in the embodiment, the N-type semiconductor layer 141, the intrinsic semiconductor layer 142 and the film layer to be processed are all formed using a CVD process. The CVD process is typically conducted in a high-temperature environment, which promotes atomic diffusion and facilitates a formation of high-quality crystal structures. The film layer formed by the CVD process exhibits high purity, good density, low residual stress, and excellent crystallinity, which are critical for enhancing an electrical performance and reliability of semiconductor devices. Therefore, in the embodiment, the CVD process is used to form the N-type semiconductor layer 141, the intrinsic semiconductor layer 142 and the film layer to be processed, so as to enhance a film quality of the N-type semiconductor layer 141, the intrinsic semiconductor layer 142 and the film layer to be processed, thereby improving the photoelectric performance of the formed PIN diode 14.

The device used in the CVD process is relatively simple and easy to operate and maintain, which helps reduce production costs and improve production efficiency.

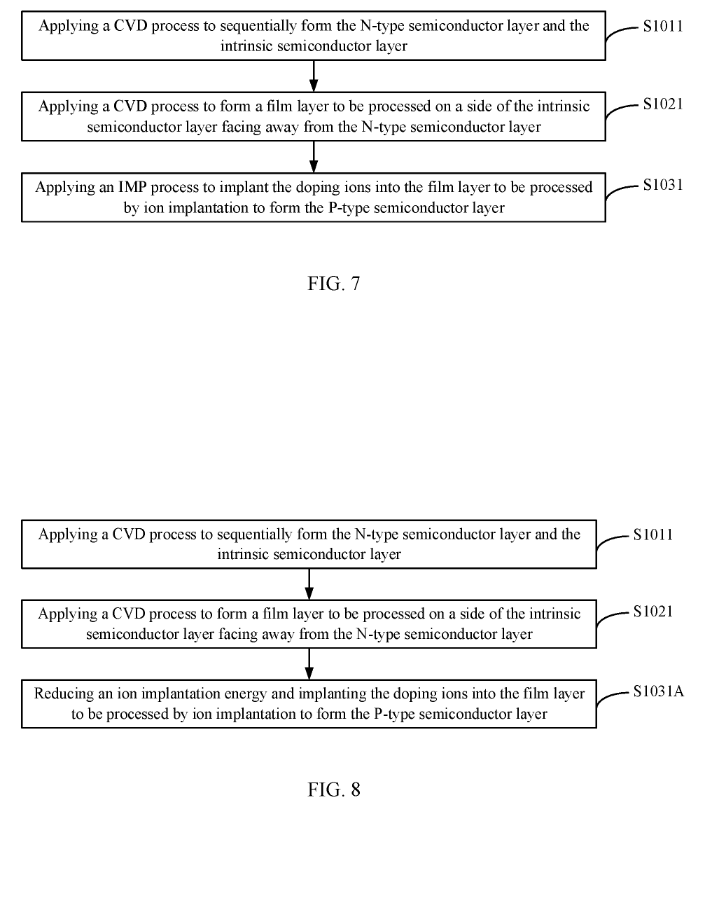

FIG. 7 illustrates a flow chart of a method for forming another PIN diode consistent with various embodiments of the present disclosure. In one optional embodiment, an implementation method of S103, ‘implanting doping ions into the film layer to be processed by ion implantation to form the P-type semiconductor layer 143,’ is as follows:

S1031: applying an IMP process to implant the doping ions into the film layer to be processed by ion implantation to form the P-type semiconductor layer 143.

Specifically, in the embodiment, the P-type semiconductor layer 143 is formed by using an IMP process, in which doping ions are implanted into the film layer to be processed. The IMP process enables precise control of material's electrical properties by implanting high-energy ion beams into the semiconductor material, allowing accurate regulation of the quantity, depth, and spatial distribution of the implanted ions. Therefore, in the embodiment, the IMP process allows accurate control of the ion implantation depth of the first doping ions, ensuring that the ion implantation depth of the first doping ion is less than the thickness of the P-type semiconductor layer 143. The area of the P-type semiconductor layer 143 where the first doping ions are not directly implanted serves as a diffusion space for the first doping ions, thereby minimizing the depth of the first doped ions diffusing into the intrinsic semiconductor layer 142, which leads to a smaller PN junction space charge region, a relatively wider depletion layer, an increase in the number of generated minority carriers, and a higher photocurrent, thereby ensuring the photoelectric performance of the PIN diode 14.

Compared with other doping processes, the IMP process operates at relatively low temperatures, which helps to reduce thermal damage to materials. The doping ions implanted by the IMP process are not limited by a solubility of a target material, exhibit high purity, and achieve uniform doping distribution over a large area, thereby ensuring the film quality of the formed P-type semiconductor layer 143 and ultimately improve the photoelectric performance of the formed PIN diode 14.

FIG. 8 illustrates a flow chart of a method for forming another PIN diode consistent with various embodiments of the present disclosure. In one optional embodiment, an implementation method of S1031, ‘applying an IMP process to implant the doping ions into the film layer to be processed by ion implantation to form the P-type semiconductor layer 143,’ is as follows:

S1031A: reducing an ion implantation energy and implanting the doping ions into the film layer to be processed by ion implantation to form the P-type semiconductor layer 143.

Specifically, in one embodiment, the ion implantation energy significantly influences the ion diffusion depth, while a photocurrent magnitude depends on a concentration and a movement speed of minority carriers in the PIN diode 14. By reducing the ion implantation energy, the ion diffusion depth decreases, leading to a smaller PN junction space charge region, a relatively wider depletion layer, an increased number of generated minority carriers, and a higher photocurrent, thereby ensuring the photoelectric performance of the PIN diode 14.

For example, the ion implantation energy can be reduced to less than 16 K, allowing the doping ions to be implanted into the film layer to be processed and form the P-type semiconductor layer 143, thereby minimizing the diffusion depth of the first doped ions into the intrinsic semiconductor layer 142 and ensuring the photoelectric performance of the PIN diode 14.

Technical effects that can be achieved by a solution of the embodiment will be further described below with specific experimental data.

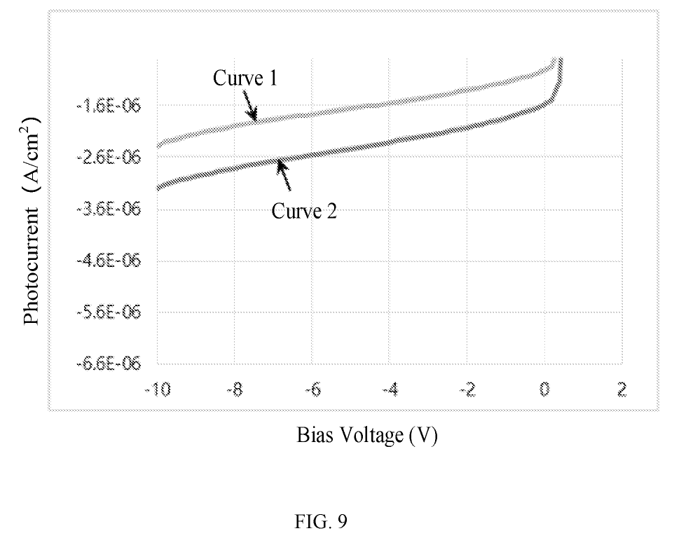

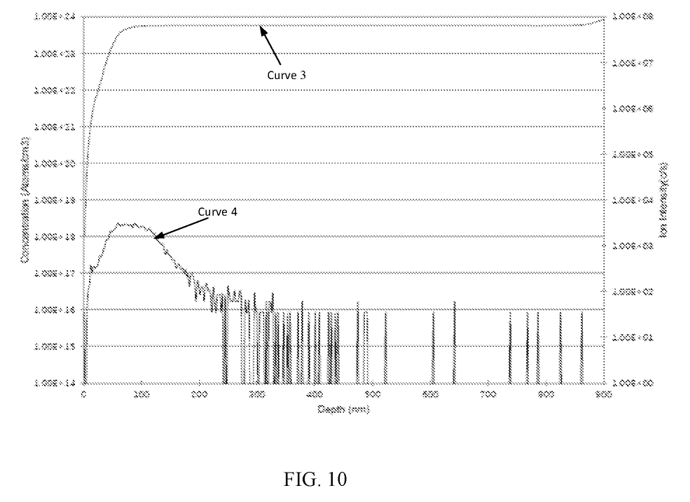

FIG. 9 illustrates a schematic diagram of a corresponding photocurrent under different ion implantation energies with a same first ion implantation dose consistent with various embodiments of the present disclosure.

Curve 1 in FIG. 9 represents the photocurrent curve of the PIN diode 14, where the P-type semiconductor layer 143 is formed by a first ion implantation energy with first ion implantation dose. Curve 2 represents the photocurrent curve of the PIN diode 14, where the P-type semiconductor layer 143 is formed by a second ion implantation energy with a same first ion implantation dose. In FIG. 9, an abscissa represents a reverse bias voltage applied to the P-type semiconductor layer 143 and the N-type semiconductor layer 141, and an ordinate represents the photocurrent. The first ion implantation energy is greater than the second ion implantation energy, and both the first ion implantation energy and the second ion implantation energy are less than 16K.

Experimental test results indicate that reducing the ion implantation energy in the IMP process during a formation of the P-type semiconductor layer 143 significantly increases the photocurrent of the PIN diode 14.

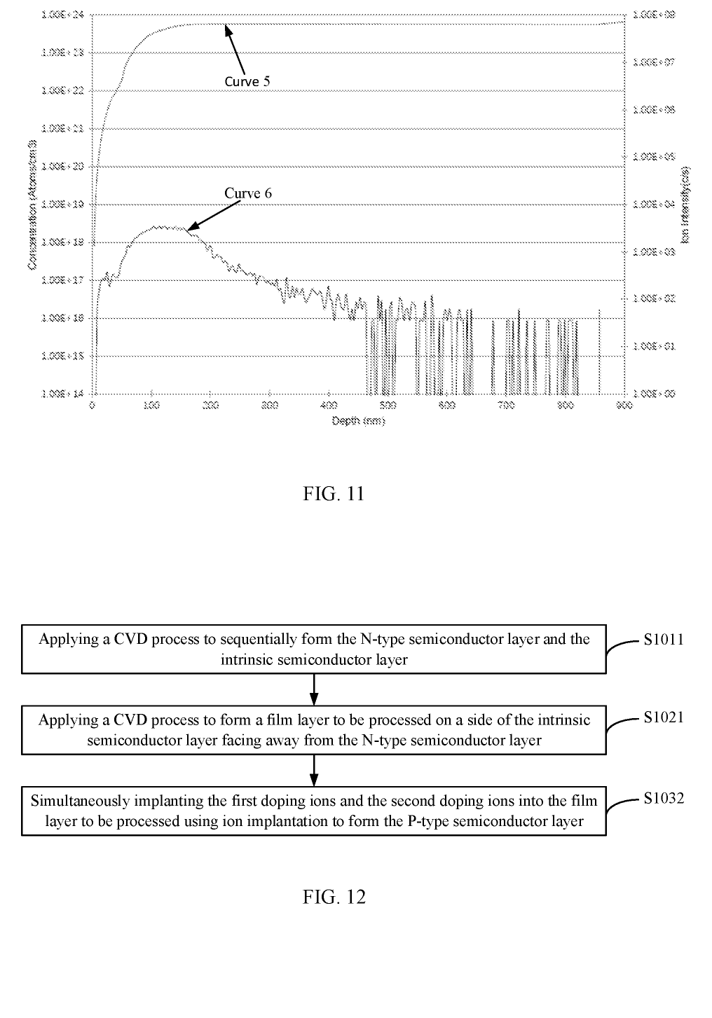

FIG. 10 illustrates a schematic diagram of a projection range under a first ion implantation energy and a first ion implantation dose consistent with various embodiments of the present disclosure. FIG. 11 illustrates a schematic diagram of a projection range under a second ion implantation energy and a first ion implantation dose consistent with various embodiments of the present disclosure.

In other words, FIG. 10 illustrates an RP schematic diagram under the first ion implantation energy and the first ion implantation dose consistent with various embodiments of the present disclosure. FIG. 11 illustrates an RP schematic diagram under the second ion implantation energy and the first ion implantation dose consistent with various embodiments of the present disclosure, which reflects an average penetration depth of ion implantation through the IMP process.

Curve 3 in FIG. 10 represents a distribution curve of a major element during testing, such as the Si element, while Curve 4 represents a distribution curve of the first doping element, such as the B element. Similarly, Curve 5 in FIG. 11 corresponds to a major element (e.g., Si), and Curve 6 corresponds to a first doping element (e.g., B) during testing.

In FIGS. 10 and 11, an abscissa represents the ion implantation depth. A left ordinate indicates a concentration, with an original signal calibrated and converted into a physical quantity. A right ordinate represents a signal intensity directly measured in a D-SIMS test.

According to a D-SIMS analysis of experimental test results, an RP value in FIG. 10 is about 34.6 nm, while an RP value in FIG. 11 is about 15 nm, indicating that reducing the ion implantation energy in the IMP process during a forming the P-type semiconductor layer 143 can significantly reduce the ion implantation depth, thereby minimizing the diffusion depth of the first doped ions into the intrinsic semiconductor layer 142. As a result, the PN junction space charge region becomes smaller, the depletion layer becomes relatively wider, the number of generated minority carriers increases, and the photocurrent increases, thereby ensuring the photoelectric performance of the PIN diode 14.

FIG. 12 illustrates a flow chart of a method for forming another PIN diode consistent with various embodiments of the present disclosure. In one optional embodiment, the doping ions also include second doping ions, and an ion mass of the second doping ions is greater than an ion mass of the first doping ions. In S103, another implementation method of ‘implanting doping ions into the film layer to be processed by ion implantation to form the P-type semiconductor layer 143’ is as follows:

S1032: simultaneously implanting the first doping ions and the second doping ions into the film layer to be processed using ion implantation to form the P-type semiconductor layer 143.

Specifically, in the embodiment, an IMP process is used to simultaneously implant the first doping ions and the second doping ions into the film layer to be processed by ion implantation to form the P-type semiconductor layer 143.

The first doping ions are B ions, that is, the P-type semiconductor layer is formed by implanting B ions. The second doping ions include, but are not limited to, at least one of F ions and Ar ions. At a same ion implantation energy, ions with greater mass move more slowly, while lighter ions move faster. To prevent the first doping ions from moving too quickly and penetrating too deeply, the second doping ions are co-implanted with the first doping ions. The second doping ions are used to slow down or buffer the diffusion of the first doping ions into deeper areas, thereby minimizing the diffusion depth of the first doping ions into the intrinsic semiconductor layer 142 and ensuring the optoelectronic performance of the PIN diode 14.

From another perspective, introducing second doping ions, such as Ar ions and/or F ions, reduces the proportion of B ions, so that under a same ion implantation energy, both the implantation depth and dose decrease, thereby achieving a goal of reducing the B ion diffusion depth.

Technical effects that can be achieved by a solution of the embodiment will be further described below with specific experimental data.

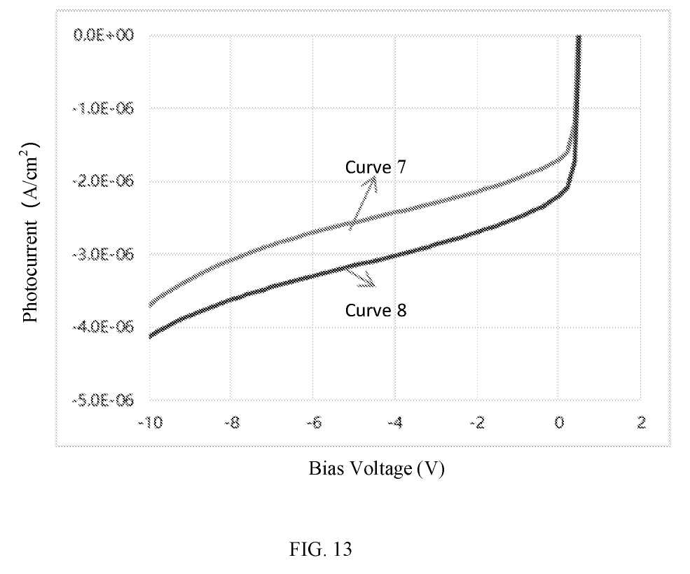

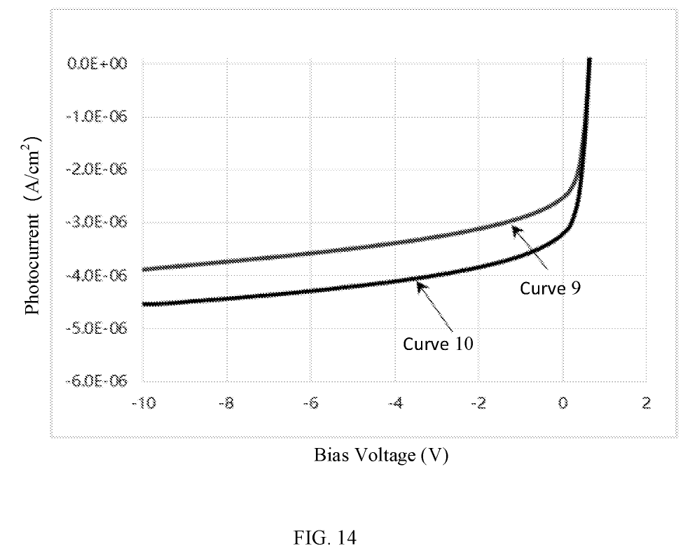

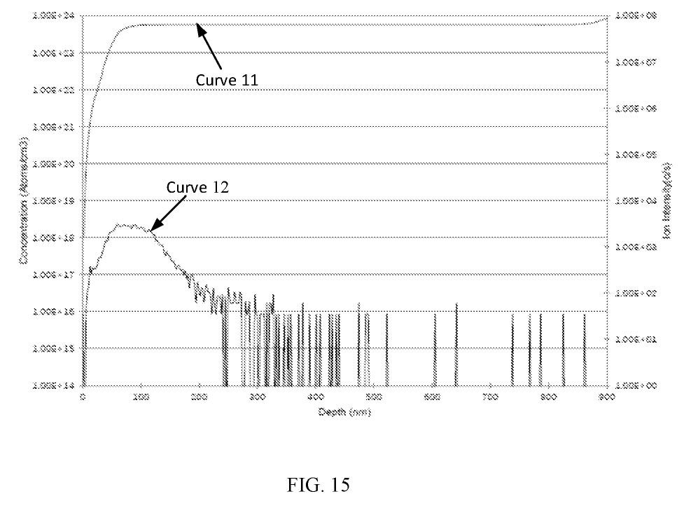

FIG. 13 illustrates a schematic diagram of a corresponding photocurrent under a first ion implantation energy and different doping ions consistent with various embodiments of the present disclosure. FIG. 14 illustrates a schematic diagram of a corresponding photocurrent under a second ion implantation energy and different doping ions consistent with various embodiments of the present disclosure.

Curve 7 in FIG. 13 represents the photocurrent curve of the PIN diode 14, where the P-type semiconductor layer 143 is formed under the first ion implantation energy by only implanting B doping ions to form B doping. A dose of B-doped ions is the first ion implantation dose. Curve 8 represents the photocurrent curve of the PIN diode 14, where the P-type semiconductor layer 143 is formed under the first ion implantation energy by implanting B doping ions and F doping ions to form BF doping. A total dose of BF doping is the first ion implantation dose. In FIG. 13, an abscissa represents a reverse bias voltage applied to the P-type semiconductor layer 143 and the N-type semiconductor layer 141, and an ordinate represents the photocurrent of the PIN diode 14.

Curve 9 in FIG. 14 represents the photocurrent curve of the PIN diode 14, where the P-type semiconductor layer 143 is formed under the second ion implantation energy by implanting B doping ions and F doping ions to form BF doping. A total dose of BF doping is the first ion implantation dose. Curve 10 represents the photocurrent curve of the PIN diode 14, where the P-type semiconductor layer 143 is formed under the second ion implantation energy by implanting B doping ions and F doping ions to form BF2 doping. A total dose of BF2 doping is the first ion implantation dose. In FIG. 14, an abscissa represents a reverse bias voltage applied to the P-type semiconductor layer 143 and the N-type semiconductor layer 141, and an ordinate represents the photocurrent.

Experimental results indicate that when the P-type semiconductor layer 143 is formed using the IMP process with an introduction of F doping ions, the proportion of B doping ions is reduced. As a result, both the implantation depth and dose become smaller under a same ion implantation energy, reducing the diffusion depth of B doping ions. It is verified that the photocurrent of the PIN diode 14 with BF2 doping is significantly better than the photocurrent of the PIN diode 14 with BF doping, and the photocurrent of the PIN diode 14 with BF doping is significantly better than the photocurrent of the PIN diode 14 with B doping.

Similarly, when the P-type semiconductor layer 143 is formed using the IMP process, and Ar doping ions are introduced, a proportion of B doping ions is reduced. As a result, under same ion implantation energy, both the implantation depth and dose decrease, thereby reducing the diffusion depth of B doping ions. It is verified that the photocurrent of the PIN diode 14 with B and Ar co-doping is significantly higher than the photocurrent of the PIN diode 14 with only B doping.

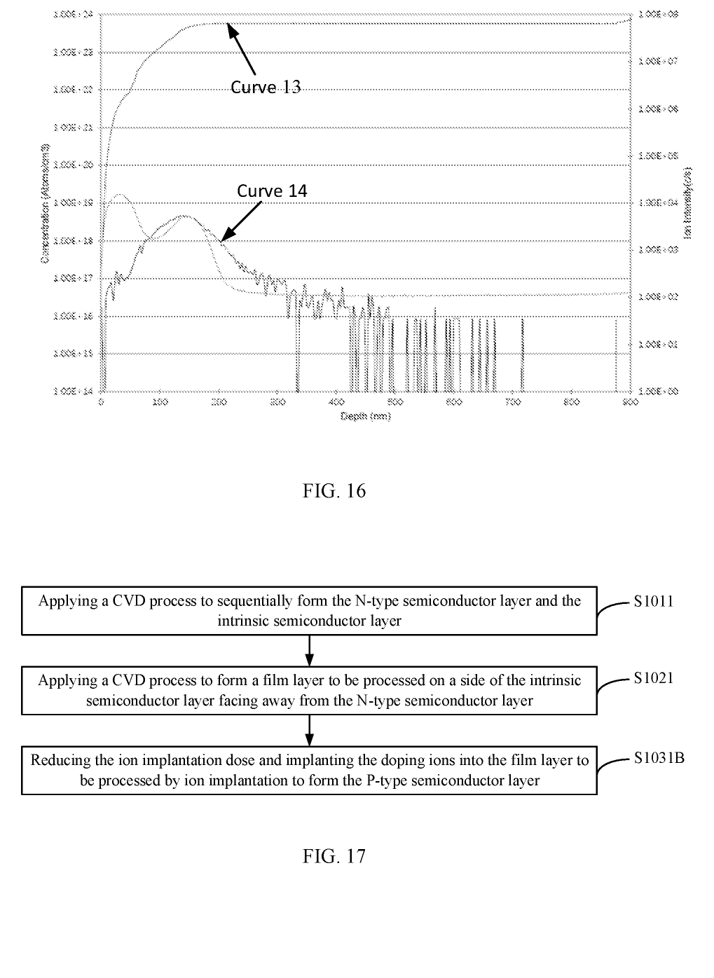

FIG. 15 illustrates a schematic diagram of a projection range under a first ion implantation energy, B doping, and a first ion implantation dose of B doping ions consistent with various embodiments of the present disclosure. FIG. 16 illustrates a schematic diagram of a projection range under a first ion implantation energy and BF doping, with a total dose of BF doping being a first ion implantation dose, consistent with various embodiments of the present disclosure.

In other words, FIG. 15 illustrates an RP schematic diagram of a first ion implantation energy, B doping, and the dose of B doped ions is the first ion implantation dose consistent with various embodiments of the present disclosure. FIG. 16 illustrates an RP schematic diagram of a first ion implantation energy and BF doping, with a total dose of BF doping being the first ion implantation dose, consistent with various embodiments of the present disclosure, which reflects the average penetration depth of ion implantation in the IMP process.

Curve 11 in FIG. 15 represents a curve corresponding to a major element during testing, such as a Si element; Curve 12 represents a curve corresponding to B doping during testing. Curve 13 in FIG. 16 represents the curve corresponding to a major element during testing, such as a Si element. Curve 14 represents a curve corresponding to BF doping during testing.

An abscissa in FIGS. 15 and 16 represents an ion implantation depth. A left ordinate indicates a concentration, with an original signal converted into a physical quantity through calibration. A right ordinate represents a signal intensity directly measured in a D-SIMS test.

According to a D-SIMS analysis of experimental test results, an RP value in FIG. 15 is about 34.6nm, and the RP value in FIG. 16 is about 12nm, indicating that the ion implantation depth of BF is significantly smaller than the ion implantation depth of B, thereby minimizing the depth of diffusion of doped ions into the intrinsic semiconductor layer 142. As a result, the PN junction space charge region becomes smaller, the depletion layer becomes relatively wider, the number of generated minority carriers increases, and the photocurrent improves, thereby ensuring the photoelectric performance of the PIN diode 14.

FIG. 17 illustrates a flow chart of a method for forming another PIN diode consistent with various embodiments of the present disclosure. In one optional embodiment, process parameters of the IMP process also include ion implantation dose. Another implementation method of S1031, ‘applying an IMP process to implant the doping ions into the film layer to be processed by ion implantation to form the P-type semiconductor layer 143,’ is as follows:

S1031B: reducing the ion implantation dose and implanting the doping ions into the film layer to be processed by ion implantation to form the P-type semiconductor layer 143.

Specifically, in the embodiment, the ion implantation energy significantly influences an ion diffusion depth, while a photocurrent magnitude depends on concentration and movement speed of minority carriers in the PIN diode 14. By reducing the ion implantation energy, the ion diffusion depth decreases, leading to a smaller PN junction space charge region, a relatively wider depletion layer, an increased number of generated minority carriers, and a higher photocurrent, thereby ensuring the photoelectric performance of the PIN diode 14

For example, the ion implantation dose can be reduced to a range of 5×10¹² ions/cm² to 5×10¹⁴ ions/cm². Doping ions can be implanted into the film layer to be processed to form the P-type semiconductor layer 143, thereby minimizing the diffusion depth of the first doping ions into the intrinsic semiconductor layer 142 and ensuring the photoelectric performance of the PIN diode 14.

Technical effects that can be achieved by a solution of the embodiment will be further described below with specific experimental data.

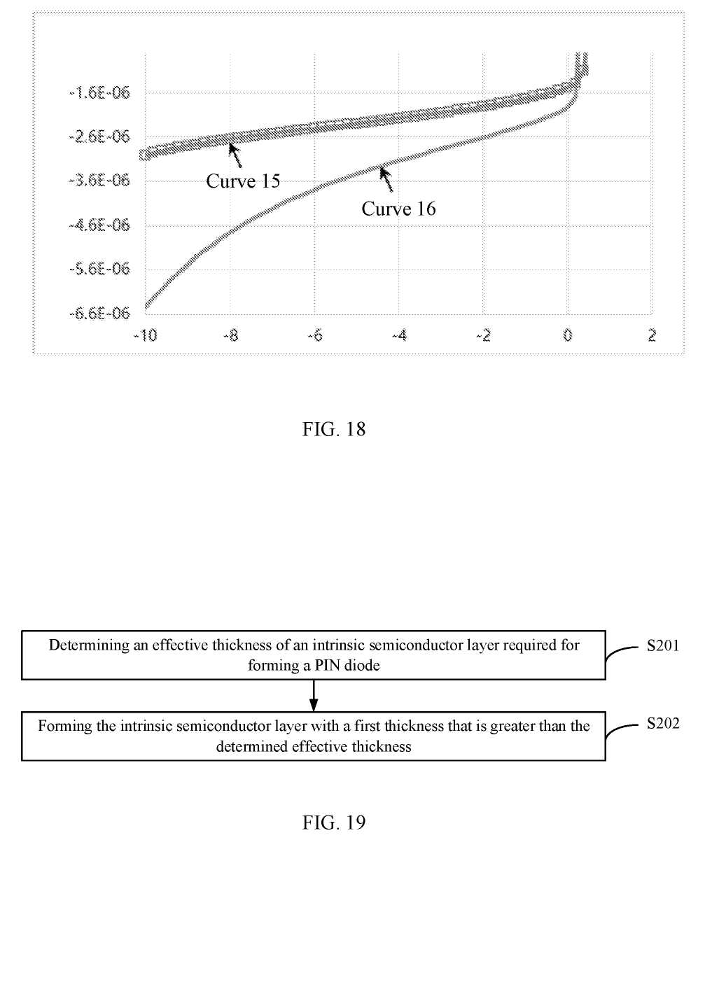

FIG. 18 illustrates a schematic diagram of a corresponding photocurrent under the same ion implantation energy and different ion implantation doses consistent with various embodiments of the present disclosure.

Curve 15 in FIG. 18 represents the photocurrent curve of the PIN diode 14, where the P-type semiconductor layer 143 is formed by the first ion implantation dose. Curve 16 represents the photocurrent curve of the PIN diode 14, where the P-type semiconductor layer 143 is formed by the second ion implantation dose. In FIG. 18, an abscissa represents a reverse bias voltage applied to the P-type semiconductor layer 143 and the N-type semiconductor layer 141. An ordinate represents the photocurrent of the PIN diode 14. The first ion implantation dose is greater than the second ion implantation dose.

It can be concluded from experimental test results that reducing the ion implantation dose of doping ions during a formation of the P-type semiconductor layer 143 using the IMP process can significantly increase the photocurrent of the PIN diode 14.

As can be seen from the above description, in the embodiment, the IMP process is used to form the P-type semiconductor layer 143 by ion implantation, with at least the ion implantation energy, doping ion species, and ion implantation dose being adjusted to minimize the diffusion depth of doping ions into the intrinsic semiconductor layer 142 and to ensure the photoelectric performance of the PIN diode 14..

Obviously, in a scheme involving adjustment of ion implantation energy, doping ion type, and ion implantation dose, only one of the three parameters can be adjusted, any two parameters of the three can be adjusted, or all three can be optimized and adjusted simultaneously. In one embodiment, a main solution involves adjusting the ion implantation energy and the doping ion species either independently or simultaneously.

FIG. 19 illustrates a schematic diagram of a process for forming intrinsic semiconductor layers consistent with various embodiments of the present disclosure. In one optional embodiment, one implementation method to form the intrinsic semiconductor layer 142 is as follows:

S201: determining an effective thickness of the intrinsic semiconductor layer 142 required for forming the PIN diode 14.

S202: forming the intrinsic semiconductor layer 142 with a first thickness that is greater than the determined effective thickness.

Specifically, in the embodiment, the effective thickness of the intrinsic semiconductor layer 142 required for forming the PIN diode 14 is determined. The intrinsic semiconductor layer 142 is formed with a thickness greater than the effective thickness. An excess region between the actual thickness and the effective thickness serves as a diffusion space for the first doped ions. Even if the first doped ions diffuse into the intrinsic semiconductor layer 142, a remaining undiffused portion with the effective thickness can support a normal operation of the PIN diode 14, thereby ensuring the photoelectric performance of the PIN diode 14.

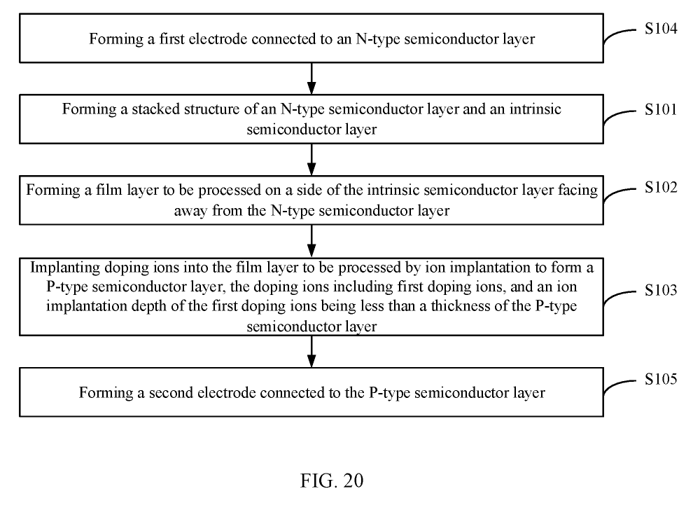

FIG. 20 illustrates a flow chart of a method for forming another PIN diode consistent with various embodiments of the present disclosure. In one optional embodiment, before forming the N-type semiconductor layer 141, the forming method of the PIN diode further includes following steps.

S104: forming a first electrode 144 connected to the N-type semiconductor layer 141.

S105: forming a second electrode 145 connected to the P-type semiconductor layer 143 after the P-type semiconductor layer 143 is formed.

In the embodiment, the anode layer 22 in the array layer 13 of the display panel 100 is connected to the P-type semiconductor layer 143 and/or the N-type semiconductor layer 141. As shown in FIG. 4, the N-type semiconductor layer 141 is electrically connected to the anode layer 22 through the first electrode 144, and the P-type semiconductor layer 143 is electrically connected to the anode layer 22 through the second electrode 145.

Since the anode layer 22 includes a plurality of independent anode units, some anode units that are not required for forming the sub-pixel 11 are used to establish electrical connections with the PIN diode 14 during a formation of the anode layer 22, thereby simplifying a circuit connection.

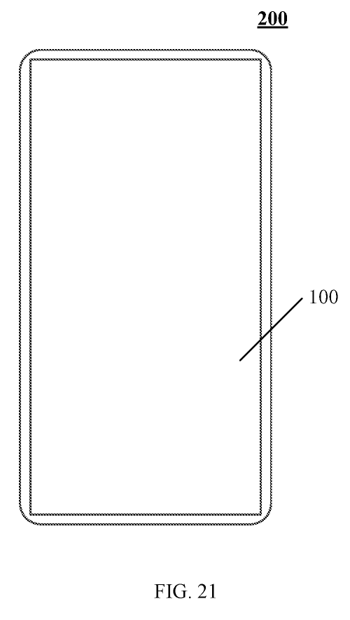

FIG. 21 illustrates a schematic diagram of a display device consistent with various embodiments of the present disclosure. In one embodiment, a display device 200 includes the display panel 100 described in the above embodiments of the present disclosure. The display device 200 may be any electronic device with a display function, such as a touch screen, a mobile phone, a tablet computer, a notebook computer, an electronic paper book or a television.

The display panel, display device, and method for forming a PIN diode provided by the present disclosure have been introduced in detail above. Specific examples are provided to illustrate principles and embodiments of the present disclosure. The descriptions of the above embodiments are intended to help understand the disclosed methods and core ideas of the present disclosure. For a person skilled in the art, variations in specific implementations and application scopes may be made based on the disclosed concepts. Therefore, the content of the present specification should not be construed as limiting the scope of the present disclosure.

It should be noted that each embodiment described in the present specification emphasizes differences from other embodiments, while same or similar components across embodiments may be referenced interchangeably.

As disclosed, the display panel, display device, and method for forming a PIN diode provided by the present disclosure at least realize the following beneficial effects.

In the present disclosure, since an array layer of the display panel uses ion implantation to form certain film layers during a forming process, a PIN diode is initially integrated and arranged within the array layer. In the forming process, a P-type semiconductor layer is also formed using a same ion implantation method, which simplifies the forming process and reduces production costs. Considering that first doped ions implanted into the P-type semiconductor layer may diffuse into an intrinsic semiconductor layer and adversely impact a photoelectric performance of the PIN diode, the present disclosure limits an ion implantation depth of the first doped ions to be less than a thickness of the P-type semiconductor layer. A portion of the P-type semiconductor layer where the first doped ions are not directly implanted serves as a diffusion space, minimizing a diffusion depth of the first doped ions into the intrinsic semiconductor layer and thereby ensuring the photoelectric performance of the PIN diode.

It should be noted that in the present specification, relationship terms such as "first" and "second" are merely used to distinguish one entity or operation from another, and do not necessarily require or imply that any actual relationship or sequence exists between these entities or operations. Moreover, the terms "include", "comprise", or their any other variants are intended to cover a non-exclusive inclusion, so that a process, a method, an article, or a terminal device that includes a list of elements not only includes those elements but also includes other elements that are not listed, or further includes elements inherent to such a process, method, article, or terminal device. Without being subject to further limitations, an element defined by a phrase "including a......." does not exclude the presence of other identical elements in the process, method, article, or terminal device that includes the very element.

The above are only specific embodiments of the present disclosure, enabling a person skilled in the art to understand or implement the present disclosure. Various modifications to the disclosed embodiments will be readily apparent to a person skilled in the art, and the general principles defined herein may be applied to other embodiments without departing from the spirit and scope of the present disclosure. Therefore, the present disclosure is not intended to be limited to the embodiments described herein but is intended to encompass a broadest scope consistent with the disclosed principles and novel features.

What is claimed is:

1. A display panel, comprising:
a substrate;
an array layer on a side of the substrate;
a PIN diode integrated within the array layer, the PIN diode including an N-type semiconductor layer, an intrinsic semiconductor layer and a P-type semiconductor layer; and
the P-type semiconductor layer including doping ions implanted based on ion implantation, the doping ions including first doping ions, and an ion implantation depth of the first doping ions being smaller than a thickness of the P-type semiconductor layer.

2. The display panel according to claim 1, wherein:
the doping ions further include second doping ions; and
an ion mass of a second doping ion of the second doping ions is greater than an ion mass of a first doping ion of the first doping ions.

3. The display panel according to claim 2, wherein the second doping ions include at least one of F ions and Ar ions.

4. The display panel according to claim 1, wherein a film formation speed of the P-type semiconductor layer is less than 25% than a film formation speed of the intrinsic semiconductor layer.

5. The display panel according to claim 1, wherein an ion implantation depth of the first doping ions is H, a thickness of the P-type semiconductor layer is G, and H=G/2.

6. The display panel according to claim 1, wherein the PIN diode also includes a first electrode connected to the N-type semiconductor layer, and a second electrode connected to the P-type semiconductor layer.

7. The display panel according to claim 1, comprising a plurality of sub-pixels on a side of the array layer facing away from the substrate, wherein:
a light-transmitting area exists between at least part of two adjacent sub-pixels; and
an orthographic projection of the light-transmissive area at least completely covers the intrinsic semiconductor layer.

8. The display panel according to claim 7, wherein:
a sub-pixel of the plurality of sub-pixels includes a stacked structure of an anode layer, a light-emitting layer, and a cathode layer; and
the anode layer is connected to the P-type semiconductor layer and/or the N-type semiconductor layer.

9. The display panel according to claim 1, wherein the PIN diode is a photoelectric PIN diode.

10. A method for forming a PIN diode, comprising:
forming a stacked structure of an N-type semiconductor layer and an intrinsic semiconductor layer;
forming a film layer to be processed on a side of the intrinsic semiconductor layer facing away from the N-type semiconductor layer; and
implanting doping ions into the film layer to be processed by ion implantation to form a P-type semiconductor layer, the doping ions including first doping ions, and an ion implantation depth of the first doping ions being smaller than a thickness of the P-type semiconductor layer.

11. The method according to claim 10, the forming the stacked structure of an N-type semiconductor layer and an intrinsic semiconductor layer includes sequentially forming the N-type semiconductor layer and the intrinsic semiconductor layer using a chemical vapor deposition (CVD) process.

12. The method according to claim 10, wherein the implanting the doping ions into the film layer to be processed to form the P-type semiconductor layer by ion implantation includes applying an ion metal plasma (IMP) process to implant the doping ions into the film layer to be processed by ion implantation to form the P-type semiconductor layer.

13. The method according to claim 12, wherein process parameters of the IMP process include an ion implantation energy, the applying the IMP process to implant the doping ions into the film layer to be processed by ion implantation to form the P-type semiconductor layer includes reducing the ion implantation energy and implanting the doping ions into the film layer to be processed to form the P-type semiconductor layer.

14. The method according to claim 13, wherein the reducing the ion implantation energy and implanting the doping ions into the film layer to be processed to form the P-type semiconductor layer by ion implantation includes reducing the ion implantation energy to less than 16 K and implanting the doping ions into the film layer to be processed to form the P-type semiconductor layer.

15. The method according to claim 10, wherein:
the doping ions further include second doping ions, and an ion mass of a second doping ion of the second doping ions is greater than an ion mass of a first doping ion of the first doping ions; and
the implanting doping ions into the film layer to be processed to form the P-type semiconductor layer includes simultaneously implanting the first and second doping ions into the film layer to be processed to form the P-type semiconductor layer.

16. The method according to claim 12, wherein process parameters of the IMP process further include an ion implantation dose, applying the IMP process to implant the doping ions into the film layer to be processed by ion implantation to form the P-type semiconductor layer includes reducing the ion implantation dose and implanting the doping ions into the film layer to be processed by ion implantation to form the P-type semiconductor layer.

17. The method according to claim 16, wherein the reducing the ion implantation dose and implanting the doping ions into the film layer to be processed to form the P-type semiconductor layer includes reducing the ion implantation dose to a range of 5×10¹² ions/cm² to 5×10¹⁴ ions/cm², and implanting the doping ions into the film layer to be processed to form the P-type semiconductor layer.

18. The method according to claim 10, forming the intrinsic semiconductor layer includes:
determining an effective thickness of the intrinsic semiconductor layer required for forming the PIN diode; and
forming the intrinsic semiconductor layer to a first thickness greater than the effective thickness.

19. The method according to claim 10, comprising:
forming a first electrode connected to the N-type semiconductor layer before forming the N-type semiconductor layer; and
forming a second electrode connected to the P-type semiconductor layer.

20. A display device comprising a display panel, comprising:
a substrate;
an array layer on a side of the substrate;
a PIN diode integrated within the array layer, the PIN diode including an N-type semiconductor layer, an intrinsic semiconductor layer and a P-type semiconductor layer; and
the P-type semiconductor layer including doping ions implanted based on ion implantation, the doping ions including first doping ions, and an ion implantation depth of the first doping ions being smaller than a thickness of the P-type semiconductor layer.
